(19) United States
(12) Patent Application Publication
(10) Pub. No.: US 2007/0108874 A1
(43) Pub. Date: May 17, 2007

(54) Piezoelectric electroacoustic transducer

(76) Inventors: Susumu Okazaki, Toyama-ken (JP); Tetsuo Takeshima, Shiga-ken (JP); Shigemasa Kusabiraki, Toyama-ken (JP); Keiichi Kami, Toyama-ken (JP)

Correspondence Address: MURATA MANUFACTURING COMPANY, LTD.;C/O KEATING & BENNETT, LLP, 8180 GREENSBORO DRIVE, SUITE 850, MCLEAN, VA, 22102, US

(21) Appl. No.: 10/562,581

(22) PCT Filed: May 27, 2005
(86) PCT No.: PCT/JP05/09745

§ 371 Date: Dec. 28, 2005

(30) Foreign Application Priority Data
Aug. 12, 2004 (JP) 2004-235029

(51) Int. Cl. H01L 41/053

(52) U.S. Cl. 310/348

(57) ABSTRACT

A piezoelectric electroacoustic transducer includes a quadrilateral piezoelectric diaphragm, a case for accommodating the piezoelectric diaphragm, and terminals fixed to the case so that inner connecting portions thereof are exposed on the inside of the case. Conductive adhesives are applied between lead electrodes of the piezoelectric diaphragm and inner connecting portions of the terminals. The conductive adhesives are applied to positions near two adjacent corners of the piezoelectric diaphragm.

### BACKGROUND OF THE INVENTION

1. Field of the Invention

The present invention relates to a piezoelectric electroacoustic transducer, such as a piezoelectric sound device, a piezoelectric receiver, or a piezoelectric speaker.

2. Description of the Related Art

Conventionally, a piezoelectric electroacoustic transducer is widely used for electronics, home electric appliances, and mobile phones as a piezoelectric sound device for generating a warning or an operating sound or as a piezoelectric receiver. The above-mentioned piezoelectric electroacoustic transducer uses a quadrilateral piezoelectric diaphragm, thereby improving the production efficiency and the efficiency of the acoustic transducer and reducing the size.

Japanese Unexamined Patent Application Publication No. 2003-9286 proposes a piezoelectric electroacoustic transducer in which a quadrilateral piezoelectric diaphragm is accommodated in a case, the outer circumference of the piezoelectric diaphragm is supported by a supporting portion disposed on the inner circumference of the case, and an elastic sealant, e.g., silicone rubber, seals the space between the outer circumference of the piezoelectric diaphragm and the inner circumference of the case. In this case, conductive adhesives connect lead electrodes of the piezoelectric diaphragm and terminals fixed to the case so as to input an electrical signal to the piezoelectric diaphragm.

Generally, the conductive adhesive contains thermoset as a basic member and a filler. Therefore, the conductive adhesive has a high Young's modulus after hardening and easily restricts the diaphragm. Further, the hardening contraction stress of the conductive adhesive generates significant distortion of the diaphragm. Recently, a diaphragm used for a piezoelectric electroacoustic transducer is excessively thin and small, and has a thickness of several tens to several hundreds μm. Therefore, the conductive adhesive, even with an excessively small coat, seriously influences the vibrating property of diaphragm.

Conventionally, in order to minimize the constraining force on the piezoelectric diaphragm due to the conductive adhesive, an elastic adhesive, e.g., urethane resin, is applied between the piezoelectric diaphragm and the terminal disposed on the case, and the conductive adhesive is applied on the elastic adhesive. In this case, the conductive adhesive is applied near each of the two corners on a diagonal line of the four corners on the piezoelectric diaphragm. Since an elastic adhesive is applied under the conductive adhesive, the hardening contraction stress of the conductive adhesive is released, thereby preventing the generation of distortion of the diaphragm.

However, when the conductive adhesives are coated near two corners on a diagonal line of the piezoelectric diaphragm as mentioned above, the constraining force on the diaphragm is large and the vibration nodes are close to the inside. Therefore, the wavelength of vibration is short and the resonant frequency is high in many cases.

Further, in accordance with a change in temperature in the using environment of the transducer, the Young's modulus of the elastic adhesive or the conductive adhesive changes and therefore, the constraining force changes. As a consequence, there is a problem of a large change in resonant frequency of the diaphragm due to the change in temperature.

### SUMMARY OF THE INVENTION

In order to overcome the problems described above, preferred embodiments of the present invention provide a piezoelectric electroacoustic transducer, in which the coating positions of conductive adhesives are located such that the node of vibrations shifts to the outside, the resonant frequency of a diaphragm is lowered, and the change in the resonant frequency of the diaphragm as a result of temperature changes is small.

According to a preferred embodiment of the present invention, a piezoelectric electroacoustic transducer includes a quadrilateral piezoelectric diaphragm that is vibrated in the thickness direction by applying an alternating signal to lead electrodes, a casing having a supporting portion disposed on an inner circumference of the casing, the supporting portion supporting the outer circumference of the piezoelectric diaphragm, first and second terminals that are fixed to the casing so that inner connecting portions are exposed on the inner circumference of the casing, and conductive adhesives that are applied and hardened between the lead electrodes of the piezoelectric diaphragm and the inner connecting portions of the first and second terminals, such that the conductive adhesives electrically connect the lead electrodes to the inner connecting portions of the first and second terminals, wherein one of the conductive adhesives is applied and hardened between the inner connecting portion of the first terminal and one of the lead electrodes near one corner of the piezoelectric diaphragm, and the other conductive adhesive is applied and hardened between the inner connecting portion of the second terminal and the other lead electrode near another corner adjacent to the one corner.

In the prior art, the conductive adhesives are coated near the two corners at the diagonal positions of the diaphragm. In this case, the vibrations of the diaphragm are similar to the vibrations of a diaphragm fixed at both opposite sides thereof.

On the other hand, according to another preferred embodiment of the present invention, the conductive adhesives are coated near the corners along one side of the diaphragm and then the vibrations are obtained to vibrate the diaphragm supported at one end thereof, thereby more freely displacing the diaphragm. Thus, the node of vibrations shifts to the outside, the wavelength of the vibrations is lengthened, and the resonant frequency is lowered. Further, when the environment of the using temperature changes, the change in the resonant frequency is minimized because of the small change in the constraining force of the diaphragm due to the change in Young's modulus of the conductive adhesive.

According to another preferred embodiment, the coating position of one conductive adhesive and that of another conductive adhesive may face each other, across the piezoelectric diaphragm. Alternatively, the coating position of the one conductive adhesive and that of the other conductive adhesive may be on one side of the piezoelectric diaphragm and near the corners at both ends of the one side.

In either case, the operations and advantages of the preferred embodiments of the present invention are obtained.

When the two terminals are disposed on the two positions of the casing facing each other across the casing, the coating positions of the conductive adhesives are determined at the two positions facing each other across the piezoelectric diaphragm. The case is more preferable because the coating shape is simple and short when the two terminals are disposed on the two positions of the casing facing each other across the casing.

According to another preferred embodiment of the present invention, the piezoelectric diaphragm may be a unimorph diaphragm which is formed by adhering a quadrilateral piezoelectric member to a quadrilateral metallic plate. Alternatively, the piezoelectric diaphragm may be a bimorph diaphragm which is formed by laminating a plurality of piezoelectric ceramic layers while sandwiching an inner electrode and providing principle surface electrodes on principle surfaces of the front and back surfaces.

In the unimorph piezoelectric diaphragm, one lead electrode is an electrode disposed on the surface of the piezoelectric member and another lead electrode is the metallic plate.

Further, in the piezoelectric diaphragm with the laminated structure, one lead electrode is connected to the inner electrode and the other lead electrode is connected to the principle surface electrodes.

According to another preferred embodiment of the present invention, preferably an elastic adhesive may be coated between the piezoelectric diaphragm and the terminal and the conductive adhesive may be coated on the elastic adhesive.

An elastic sealant, e.g., silicone rubber seals the space between the outer circumference of the piezoelectric diaphragm and the inner circumference of the casing. Before the sealing operation, the piezoelectric diaphragm needs to be temporarily joined to the casing. The temporary joining operation is performed with the elastic adhesive, thereby keeping the positional precision between the piezoelectric diaphragm and the casing. Further, the conductive adhesive is constricted when hardening and therefore the hardening contraction stress affects the piezoelectric diaphragm, thereby changing the resonant frequency. However, since the elastic adhesive is coated under the conductive adhesive, the hardening contraction stress of the conductive adhesive is released by the elastic adhesive, thereby minimizing the influence of the stress on the piezoelectric diaphragm. The above-mentioned elastic member is preferably a urethane-series adhesive, for example. Preferably, the Young's modulus after the hardening may be not more than about 500×10⁶ Pa.

As will be understood, preferably the conductive adhesives are coated near the corners along one side of the diaphragm, thereby freely displacing the other three sides of the diaphragm. Thus, the node of the vibrations of the diaphragm shifts to the outside, the wavelength of the vibrations is lengthened, and the resonant frequency is lowered. Further, with the change in environment of the operation temperature, the change in the resonant frequency is minimized because of the small change in the constraining force of the diaphragm due to the change in Young's modulus of the conductive adhesive.

Other features, elements, characteristics, and advantages of the present invention will become more apparent from the following description of preferred embodiments of the present invention with reference to the attached drawings.

### BRIEF DESCRIPTION OF THE DRAWINGS

FIG. 1 is an exploded perspective view showing a piezoelectric electroacoustic transducer according to a first preferred embodiment of the present invention.

FIG. 2 is a plan view showing a diaphragm which is held to a case (before coating an elastic sealant).

FIG. 3 is an enlarged cross-sectional view along a line III-III shown in FIG. 2.

FIG. 4 is an enlarged cross-sectional view along a line IV-IV shown in FIG. 2.

FIG. 5 is a plan view showing the case used for the piezoelectric electroacoustic transducer shown in FIG. 1.

FIG. 6 is a cross-sectional view along a line VI-VI shown in FIG. 5.

FIG. 7 is a cross-sectional view along a line VII-VII shown in FIG. 5.

FIG. 8 is an enlarged perspective view showing the corner on the lower left of the case shown in FIG. 5.

FIGS. 9A and 9B are a plan view and a contour plan showing the displacement of the diaphragm according to the first preferred embodiment of the present invention.

FIGS. 10A and 10B are a plan view and a contour plan showing the displacement of the diaphragm according to a comparison with the first preferred embodiment of the present invention.

FIG. 11 is a comparing diagram showing the property of sound pressure between preferred embodiments of the present invention and the comparison.

FIG. 12 is a diagram showing the amount of change in frequency due to the change in temperature between preferred embodiments of the present invention and the comparison.

FIG. 13 is a plan view showing a piezoelectric electroacoustic transducer according to a second preferred embodiment of the present invention.

FIG. 14 is a plan view showing a piezoelectric electroacoustic transducer according to a third preferred embodiment of the present invention.

FIG. 15 is a perspective view showing a piezoelectric diaphragm used for the piezoelectric electroacoustic transducer shown in FIG. 14.

FIG. 16 is an analysis diagram showing the displacement of the diaphragm of the piezoelectric electroacoustic transducer shown in FIG. 14 using the finite element method.

FIG. 17 is a plan view according to a comparison with the third preferred embodiment of the present invention.

FIG. 18 is an analysis diagram showing the displacement of a diaphragm shown in FIG. 17 using the finite element method.

FIG. 19 is a perspective view showing a known piezoelectric diaphragm that can be modified to obtain a fourth preferred embodiment of the present invention.

FIG. 20 is a cross-sectional view along a line XX-XX shown in FIG. 19.

### DETAILED DESCRIPTION OF PREFERRED EMBODIMENTS

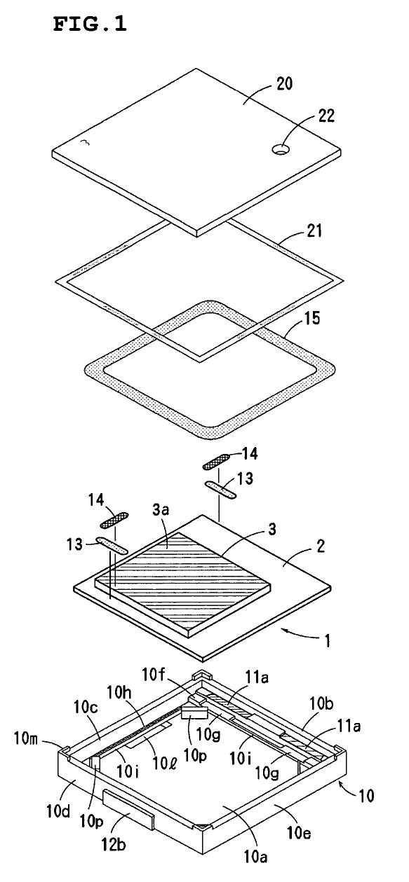

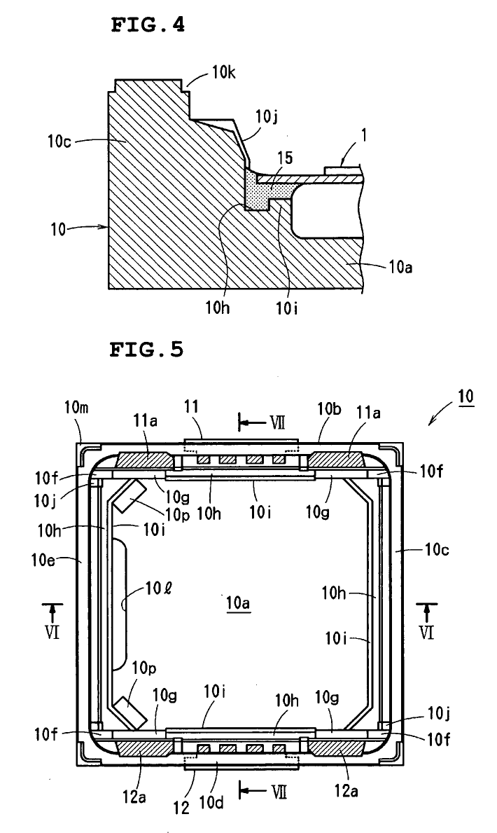

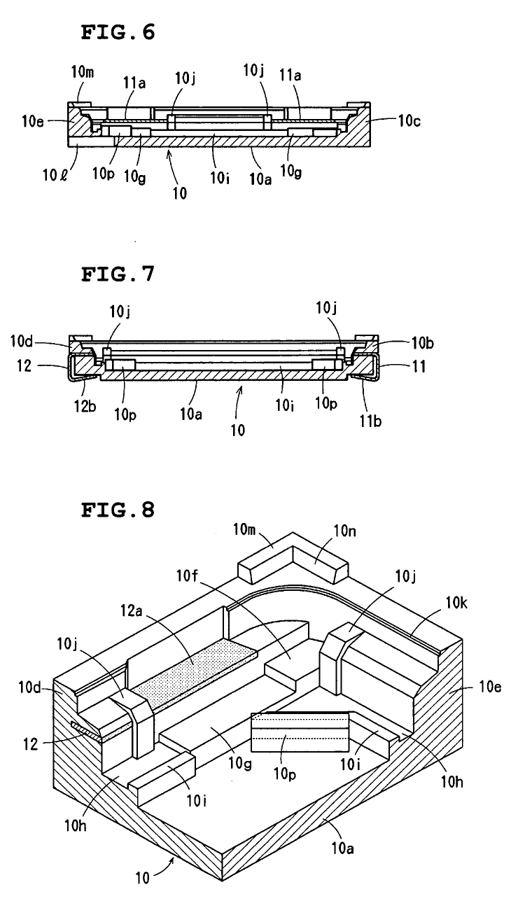

FIGS. 1 to 8 show an example of a surface mount piezoelectric electroacoustic transducer, such as a sound device or a ringer, suitable for use with a single frequency, according to preferred embodiments of the present invention.

The electroacoustic transducer mainly includes a piezoelectric diaphragm 1, a case 10, and a cover 20. Here, a casing includes the case 10 and the cover 20.

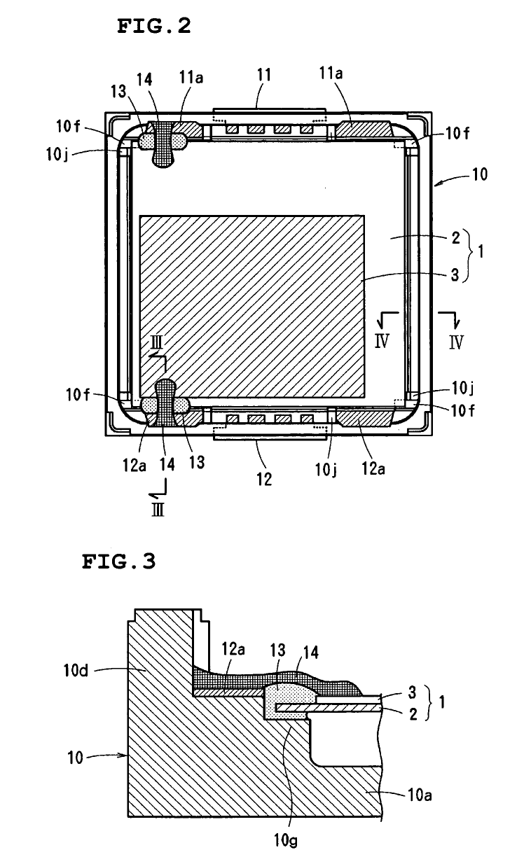

Referring to FIG. 2, the piezoelectric diaphragm 1 according to a first preferred embodiment preferably includes a square or substantially square metallic plate 2 and a piezoelectric member 3 which is adhered at the position near one corner on the top surface of the metallic plate 2. The piezoelectric member 3 according to the first preferred embodiment is preferably substantially rectangular. However, the piezoelectric member 3 may be, more specifically, substantially square or square. The piezoelectric member 3 is preferably made of piezoelectric ceramics, e.g., PZT or any other suitable ceramic. Front and back surfaces of the piezoelectric member 3 have electrodes 3a and 3b (electrode 3b on the back surface is not shown). An alternating signal is applied between the electrodes 3a and 3b on the front and back surfaces, thereby the piezoelectric member 3 expands and contracts in the planar direction of the piezoelectric member. Preferably, the metallic plate 2 has good conductivity and also spring elasticity. For example, the metallic plate 2 may be made of phosphor bronze or 42Ni. Here, the metallic plate 2 is made of 42Ni with a coefficient of thermal expansion which is approximate to that of ceramic (e.g., PZT) having, for example, the dimensions in the vertical, horizontal, and thickness directions of about 7.6 mm, about 7.6 mm, and about 0.03 mm, respectively. Further, the piezoelectric member 3 is preferably made of a PZT plate having, for example, the dimensions in the vertical, horizontal, and thickness directions of about 6.8 mm, about 5.6 mm, and about 0.04 mm, respectively.

The case 10 is preferably a substantially square or square box with a bottom wall 10a and four side walls 10b to 10e as shown in FIGS. 5 to 8, and is made of a resin material. Preferably, the resin material may be a heat-resistant resin, e.g., LCP (liquid crystal polymer), SPS (syndiotactic polystyrene), PPS (polyphenylene sulfide), epoxy, or any other suitable heat-resistant resin. Among the four side walls 10b to 10e, at the two places near the corners in the side walls 10b and 10d facing each other, bifurcated inner connecting portions 11a and 12a of terminals 11 and 12 are exposed. The terminals 11 and 12 are inserted and molded in the case 10. Outer connecting portions 11b and 12b are externally exposed on the case 10 and bent to the bottom surface of the case 10 along the outer surfaces of the side walls 10b and 10d of the terminals 11 and 12, as shown in FIG. 7.

At four inner corners of the case 10, a supporting portion 10f is arranged for supporting the bottom surface of the corner of the diaphragm 1. The supporting portion 10f is lower than the exposed surfaces of the inner connecting portions 11a and 12a of the terminals 11 and 12 by a step. Therefore, when the diaphragm 1 is placed on the supporting portion 10f, the top surface of the diaphragm 1 has the same height as the top surface of the inner connecting portions 11a and 12a of the terminals 11 and 12, or the top surface of the diaphragm 1 has a height slightly lower than the top surface of the inner connecting portions 11a and 12a of the terminals 11 and 12.

Near the supporting portion 10f and on the inner circumference of the inner connecting portions 11a and 12a of the terminals 11 and 12, a receiving step 10g has a height lower than the supporting portion 10f with a predetermined space from the bottom surface of the diaphragm 1. The space between the top surface of the receiving step 10g and the bottom surface of the diaphragm 1 (top surface of supporting portion 10f) has a dimension for preventing the flow of an elastic adhesive 13 using the surface tension of the elastic adhesive 13, which will be described later.

Further, at the circumference of the bottom wall 10a of the case 10, a groove 10h is disposed for filling with an elastic sealant 15, which will be described later. In the groove 10h, a wall 10i is disposed for preventing a flow lower than the supporting portion 10f. The wall 10i for preventing the flow regulates the flow of the elastic sealant 15 to the bottom wall 10a. The space between the top surface of the wall 10i and the bottom surface of the diaphragm 1 (top surface of the supporting portion 10f) has a dimension for preventing the flow of the elastic sealant 15 using the surface tension thereof.

According to the first preferred embodiment, the groove 10h has a low depth so that the bottom surface of the groove 10h is at a position higher than the top surface of the bottom wall 10a and the groove 10h is filled with a small amount of the elastic sealant 15 so as to quickly surround the periphery. The groove 10h and the wall 10i are disposed on the circumference of the bottom wall 10a excluding the receiving step 10g. Or, the groove 10h and the wall 10i may be continuously disposed over the entire bottom wall 10a via the inner circumference of the receiving step 10g.

Further, terminal portions (the four corners) of the groove 10h which come into contact with the supporting portion 10f and the receiving step 10g are wide, as compared with other portions. Therefore, the surplus adhesive 15 is absorbed by the wide portions preventing the flow of adhesive 15 to the diaphragm 1.

At two portions of two adjacent corners near the center of the diaphragm 1 other than the supporting portion 10f, receiving bases 10p for preventing the over-amplitude and a predetermined amount of amplitudes of the diaphragm 1 project from the bottom wall 10a of the case 10.

In the inner surfaces of the side walls 10b to 10e of the case 10, taper-shaped projecting portions 10j are disposed for guiding the four sides of the piezoelectric diaphragm 1. Two projecting portions 10j are individually disposed on each of the side walls 10b to 10e.

At the inner surfaces of the top edges of the side walls 10b to 10e of the case 10, concave portions 10k for regulating the rising of the elastic sealant 15 are provided.

Further, on the bottom wall 10a near the side wall 10e, a first sound hole 101 is provided.

On the top surfaces of the corners of the side walls 10b to 10e in the case 10, L-shaped positioning projecting portions 10m are provided for holding and fitting the corners of the cover 20. On the inner surfaces of the projecting portions 10m, taper surfaces 10n for guiding the cover 20 are provided.

Here, a description is given of an assembling method of the piezoelectric electroacoustic transducer with the above-mentioned structure.

First, the piezoelectric diaphragm 1 is accommodated in the case 10 so that the metallic plate 2 faces the bottom wall, the four corners of the piezoelectric diaphragm 1 are supported by the supporting portions 10f. In this case, the circumference of the diaphragm 1 is guided by the taper-shaped projecting portions 10j disposed on the inner surfaces of the side walls 10b to 10e of the case 10. Therefore, the corners of the diaphragm 1 are precisely placed on the supporting portions 10f.

After accommodating the diaphragm 1 in the case 10, the elastic adhesive 13 is applied to two portions near adjacent corners of the diaphragm 1, thereby temporarily fixing the diaphragm 1 (metallic plate 2) to the case 10. In particular, the metallic plate 2 is coated with elastic adhesive 13, as shown in FIG. 3. A conductive adhesive 14 coated on the elastic adhesive 13 prevents a contact state of the conductive adhesive 14 with the metallic plate 2 at the supporting portion 10f of the case. When the strength for temporary fixing of the diaphragm 1 is to be increased, the elastic adhesive 13 may coat the two remaining portions near the other adjacent corners of the diaphragm 1. Here, the elastic adhesive 13 is linearly applied to the outer side surface of the diaphragm 1. However, the coating shape is not limited to this. As the elastic adhesive 13, preferably, an adhesive with Young's modulus of about 500×10⁶ Pa or less after the hardening is used. According to the first preferred embodiment, a urethane-series adhesive with Young's modulus of about 3.7×10⁶ Pa is preferably used. After coating the elastic adhesive 13, heating and hardening processing are performed.

Upon coating the elastic adhesive 13, the elastic adhesive 13 might flow and fall to the bottom wall 10a via the space between the piezoelectric diaphragm 1 and the terminal 11 or 12. However, as shown in FIG. 3, the receiving step 10g is disposed at a lower portion of the piezoelectric diaphragm 1 in an area coated with the elastic adhesive 13. The space between the receiving step 10g and the piezoelectric diaphragm 1 is narrow. Therefore, the flow of the elastic adhesive 13 is prevented by the surface tension of the elastic adhesive 13, thereby preventing the flow to the bottom wall portion 10a. Further, since the space is quickly filled, the surplus elastic adhesive 13 forms a projecting portion between the piezoelectric diaphragm 1 and the terminal 11 or 12. The layer of the elastic adhesive 13 exists between the receiving step 10g and the piezoelectric diaphragm 1. Thus, the piezoelectric diaphragm 1 is not restrained in an unnecessary manner.

After hardening the elastic adhesive 13, the conductive adhesive 14 is applied to the upper portion of the elastic adhesive 13. Various conductive adhesives may be used. According to the first preferred embodiment, a urethane-series conductive paste is preferably used and preferably has a Young's modulus of about 0.3×10⁹ Pa after the hardening. After applying the conductive adhesive 14, the conductive adhesive 14 is heated and hardened, thereby electrically connecting the metallic plate 2 to the inner connecting portion 11a of the terminal 11 and further connecting the surface electrode 3a of the piezoelectric member 3 to the inner connecting portion 12a of the terminal 12. In particular, the application length of the conductive adhesive 14 connecting the electrode 3a of the piezoelectric member 3 to the inner connecting portion 12a of the terminal 12 is shortened because the piezoelectric member 3 is positioned near one corner of the metallic plate 2. Then, under the conductive adhesive 14, the elastic adhesive 13 exists and coats the metallic plate 2, thereby preventing the direct contact state of the conductive adhesive 14 with the metallic plate 2. The coating shape of the conductive adhesive 14 is not limited and may connect, via the top surface of the elastic adhesive 13, the metallic plate 2 or the surface electrode 3a of the piezoelectric member 3 to the inner connecting portion 11a of the terminal 11 or the inner connecting portion 12a of the terminal 12. The elastic adhesive 13 projects and therefore the conductive adhesive 14 is applied arch-like to the top surface of the elastic adhesive 13, that is, the applied conductive adhesive 14 is not the shortest route. Therefore, the hardening contraction stress of the conductive adhesive 14 is reduced by the elastic adhesive 13, thereby minimizing the influence on the diaphragm 1.

After applying and hardening the conductive adhesive 14, the elastic sealant 15 is applied to the space between the entire circumference of the diaphragm 1 and the inner circumference of the case 10, thereby preventing air leakage between the front side and the back side of the diaphragm 1. After circumferentially applying the elastic sealant 15, the elastic sealant 15 is heated and hardened. As the elastic sealant 15, a thermal hardening adhesive may be used with a Young's modulus of about 30×10⁶ Pa or less after the hardening and a low degree of viscosity before the hardening. Preferably, a silicone-series adhesive is preferably used as the elastic sealant 15, for example. At the inner circumference of the case 10 facing the circumference of the diaphragm 1, the groove 10h is disposed so as to fill with the elastic sealant 15. In the groove 10h, the wall 10i prevents the flow. The elastic sealant 15 enters the groove 10h, and is circumferentially spread. Between the diaphragm 1 and the wall 10i for preventing the flow, a space is provided for preventing the flow of the elastic sealant 15 using the surface tension thereof. The flow of the elastic sealant 15 to the bottom wall 10a is prevented. Between the wall 10i and the piezoelectric diaphragm 1, the layer of the elastic sealant 15 exists. Therefore, suppression of vibrations of the piezoelectric diaphragm 1 is prevented.

As mentioned above, after attaching the diaphragm 1 to the case 10, the cover 20 is adhered to the top surfaces of the side walls of the case 10 with an adhesive 21. The cover 20 is formed to have a planar configuration with the same material as that of the case 10. The circumference of the cover 20 is engaged with inner taper surfaces 10n of the positioning projecting portions 10m projected to the top surfaces of the side walls of the case 10, thereby performing the precise positioning. The cover 20 is adhered to the case 10, thereby forming the acoustic space between the cover 20 and the diaphragm 1. The cover 20 has a second sound hole 22.

As mentioned above, the surface mount piezoelectric electroacoustic transducer is thus assembled.

According to the first preferred embodiment, a predetermined alternating signal (AC signal or rectangular-wave signal) is applied between the terminals 11 and 12, thereby expanding and contracting the piezoelectric member 3 in the planar direction without expansion and contraction of the metallic plate 2. Therefore, as a whole, the diaphragm 1 is bent and vibrates. The elastic sealant 15 seals the interval between the front side and the back side of the diaphragm 1. Therefore, predetermined sound waves are generated through the sound hole 22.

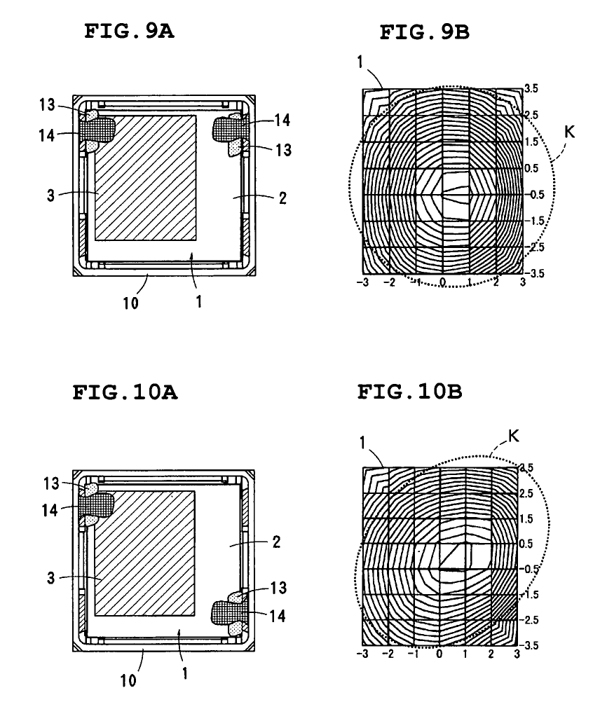

FIGS. 9A and 9B show a coating position of the conductive adhesive and the displacement of the diaphragm in the piezoelectric electroacoustic transducer according to a preferred embodiment of the present invention.

FIGS. 10A and 10B show a coating position of a conductive adhesive and the displacement of a diaphragm in a piezoelectric electroacoustic transducer according to a comparison.

According to the present preferred embodiment of the present invention, the elastic adhesive is applied near each of two adjacent corners at both ends of a side of the diaphragm 1 and the conductive adhesive 14 is applied over the top of the elastic adhesive 13. On the other hand, according to the comparison, the elastic adhesive 13 is applied near each of the two corners on a diagonal line of the diaphragm 1 and the conductive adhesive 14 is applied over the top of the elastic adhesive 13, and the diaphragm 1 and the case 10 have the same shapes that the diaphragm 1 and the case 10 have of the present preferred embodiment.

As will be understood with reference to FIGS. 10A and 10B, according to the comparison, the conductive adhesive 14 is applied near each of the two corners on a diagonal line. Then, a node K of vibrations of the diaphragm 1 is near the inside, and the displacement of vibrations is elliptical. As a result, the resonant frequency of the diaphragm 1 is high.

On the contrary, according to the present preferred embodiment of the present invention, the conductive adhesive 14 is applied near each of two adjacent corners of the diaphragm 1. Then, referring to FIG. 9B, the node K of vibrations of the diaphragm 1 shifts to the outside and the displacement of vibrations is circular without distortion. Therefore, unlike the comparison, the resonant frequency of the diaphragm 1 is lowered.

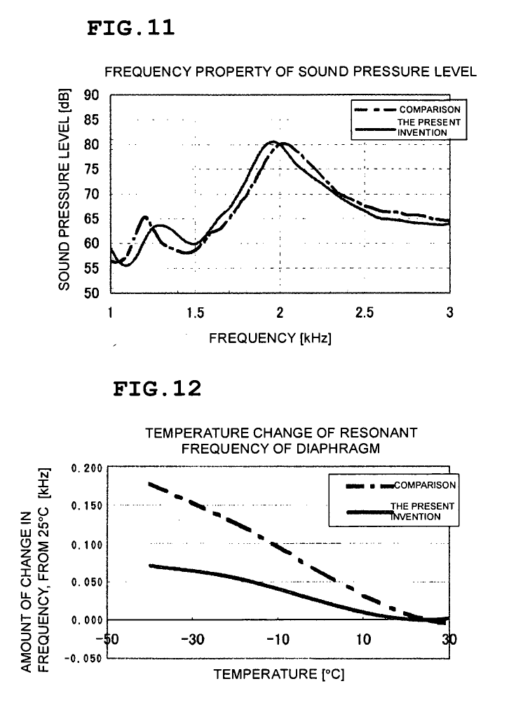

FIG. 11 shows the properties of sound pressure according to preferred embodiments of the present invention and the comparison.

According to preferred embodiments of the present invention, the peak level of the sound pressure shifts to the lower-frequency side, as compared with that according to the comparison.

FIG. 12 shows the amount of change in frequency due to the temperature change according to preferred embodiments of the present invention and the comparison.

According to the comparison, with the change in temperatures ranging from 25° C. to −40° C., the amount of change in frequency is approximately 0.18 kHz. On the contrary, according to preferred embodiments of the present invention, the amount of change in frequency is approximately 0.07 kHz. The change in frequency due to the temperature change according to preferred embodiments of the present invention is lower than the half of the comparison.

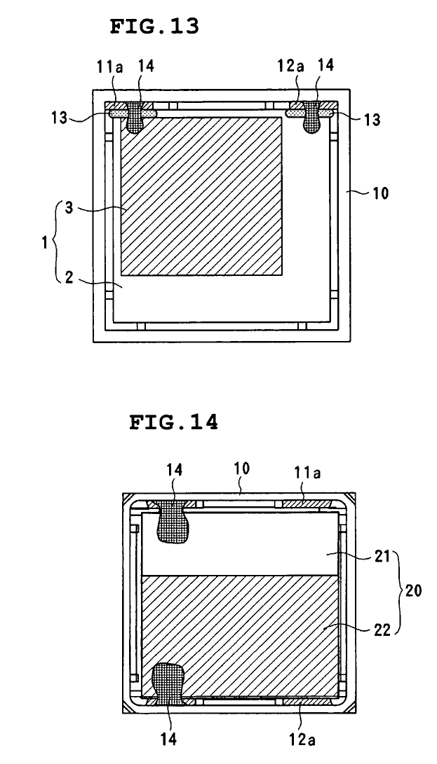

According to the first preferred embodiment, the conductive adhesive 14 is applied to the positions near two adjacent corners of the diaphragm 1. However, referring to FIG. 13, the conductive adhesive may be applied to the positions near the two corners on one side of the diaphragm 1.

The above-mentioned structure can be applied to the case in which the inner connecting portions 11a and 12a of the terminals 11 and 12 are exposed along one side of the case 10.

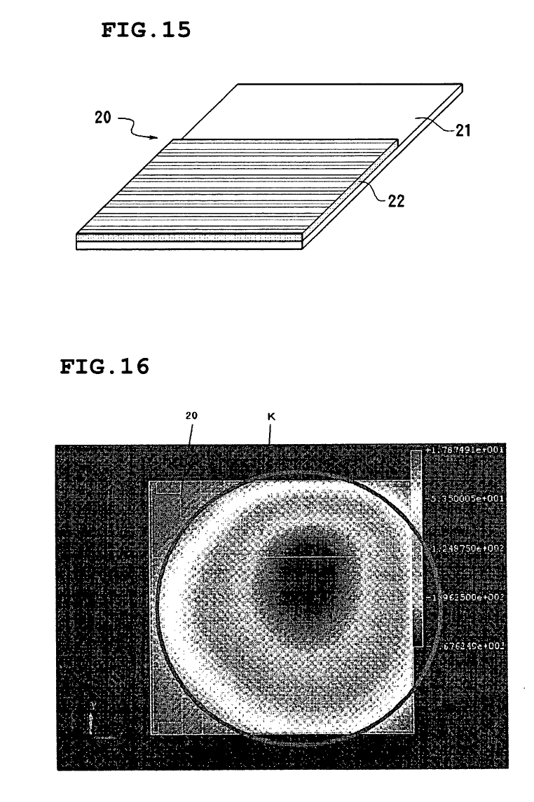

FIG. 14 shows an example of a piezoelectric electroacoustic transducer using the unimorph diaphragm 1′ with a shape different from that according to the first preferred embodiment. FIG. 15 shows the unimorph diaphragm 1′. The same portions as those according to the first preferred embodiment are designated by the same reference numerals, and a description thereof is omitted here.

Referring to FIG. 15, the diaphragm 1′ has a piezoelectric member 3′ which is adhered to the position near one side of the metallic plate 2′. Materials of the metallic plate 2′ and the piezoelectric member 3′ are preferably the same as those according to the first preferred embodiment. However, the metallic plate 2′ has the dimensions, for example, in the vertical, horizontal, and thickness directions of about 7.6 mm, about 7.6 mm, and about 0.03 mm, respectively, and the piezoelectric member 3′ has the dimensions, for example, in the vertical, horizontal, and thickness directions of about 5.3 mm, about 7.6 mm, and about 0.04 mm, respectively.

According to the third preferred embodiment, the conductive adhesive 14 is applied to the positions near the two adjacent corners of the diaphragm 1′.

FIG. 16 shows the displacement of the diaphragm 1′ when the conductive adhesive 14 is applied to the positions near two adjacent corners of the diaphragm 1′ as shown in FIG. 14.

As will be understood with reference to FIG. 16, the conductive adhesive 14 is applied to the positions near two adjacent corners of the diaphragm 1′. Therefore, the node K of the vibrations shifts to the outside and the displacement of vibrations is circular without distortion. Thus, the resonant frequency of the diaphragm 1′ is lowered.

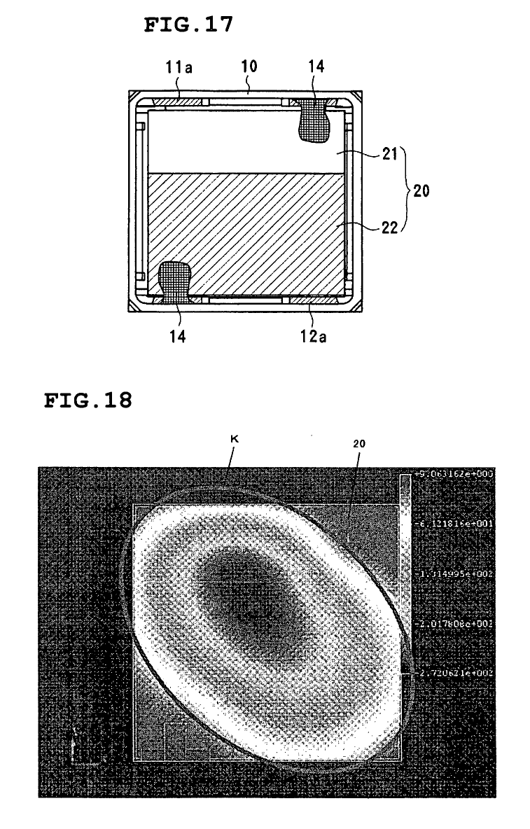

FIG. 17 shows the example in which the conductive adhesive 14 is applied to the positions near two corners on a diagonal line with the diaphragm 1′ of the third preferred embodiment. FIG. 18 shows the displacement of the diaphragm 1′.

Referring to FIG. 18, the node K of the vibrations of diaphragm 1′ is near the inside at the two corners on the diagonal line on which the conductive adhesive 14 is disposed, and the displacement of vibrations is elliptically distorted. As a result, the resonant frequency of the diaphragm 1′ is high.

As will be understood according to the first and third preferred embodiments, the conductive adhesive is applied to the positions near two adjacent corners of the diaphragm, independently of the shapes of the diaphragms 1 and 1′. The node K of the vibrations shifts to the outside and the resonant frequency is lowered.

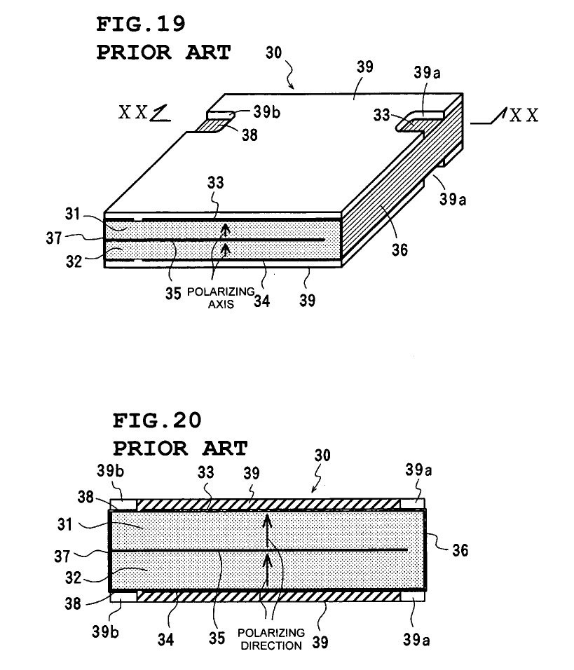

The piezoelectric diaphragm is not limited to the unimorph diaphragm which is formed by adhering the piezoelectric member to the metallic plate and may be a piezoelectric diaphragm with a bimorph structure having laminated layers of piezoelectric ceramic, as shown in FIGS. 19 and 20.

A diaphragm 30 is disclosed in, e.g., Japanese Unexamined Patent Application Publication No. 2001-95094. The diaphragm 30 is formed by laminating two piezoelectric ceramic layers 31 and 32, the principal surfaces on the front and back sides of the diaphragm 30 have principle surface electrodes 33 and 34, and an inner electrode 35 is formed between the ceramic layers 31 and 32. The two ceramic layers 31 and 32 are polarized in the same direction as the thickness. The principle surface electrode 33 on the front side and the principle surface electrode 34 on the back side are provided with lengths shorter than that of the side of the diaphragm 30, and first ends of the principle surface electrode 33 on the front side and the principle surface electrode 34 on the back side are connected to an end electrode 36 provided on one end surface of the diaphragm 30. Therefore, the principle surface electrode 33 on the front side and the principle surface electrode 34 on the back side are connected to each other. The inner electrode 35 is symmetrically formed with respect to the principle surface electrodes 33 and 34, one end of the inner electrode 35 is separated from the end electrode 36, and the other end of the inner electrode 35 is connected to an end electrode 37 provided on another end surface of the diaphragm 30. An auxiliary electrode 38 which is conductive to the end electrode 37 is provided on the front and back surfaces of the other end of the diaphragm 30.

On the front and back surfaces of the diaphragm 30, a resin layer 39 is provided for coating the principle surface electrodes 33 and 34. The resin layer 39 is disposed so as to improve the strength against dropping because the diaphragm 30 is made of ceramic material. Then, the resin layer 39 on the front and back sides includes a notch 39a, in which the principle surface electrodes 33 and 34 are exposed, and a notch 39b in which the auxiliary electrode 38 is exposed, near two adjacent corners of the diaphragm 30.

The notches 39a and 39b may be disposed only on one of the front and back surfaces. In the present preferred embodiment, to obtain the non-directivity of the front and back sides, the notches 39a and 39b are disposed on both the front and back surfaces.

Further, the auxiliary electrode 38 does not need to have a band electrode with a constant width. The auxiliary electrode may be disposed only at the position corresponding to the notch 39b.

The diaphragm 30 is accommodated in the case 10 similarly to that shown in FIGS. 5 to 8, the elastic adhesive 13 is applied between the principle surface electrode 33 exposed in the notch 39a at the facing position and the inner connecting portion 11a of the terminal 11, and between the auxiliary electrode 38 exposed in the notch 39b and the inner connecting portion 12a of the terminal 12, and the diaphragm 30 is temporarily fixed to the case 10.

After that, similar to the first preferred embodiment, the conductive adhesive 14 is applied on the elastic adhesive 13 and is hardened. Further, the elastic sealant 15 is applied to seal the space between the outer circumference of the diaphragm 30 and the inner circumference of the case 10.

According to the fourth preferred embodiment, the conductive adhesive 14 is applied to the positions near adjacent corners of the diaphragm 30. Therefore, the constraining force of the diaphragm 30 is lowered, as compared with the case of applying the conductive adhesive to the positions near two corners on a diagonal line. Accordingly, the node of vibrations shifts to the outside and the resonant frequency is lowered.

The present invention is not limited to the above-mentioned preferred embodiments and can be modified without departing from the essentials of the present invention.

According to the present preferred embodiment, the piezoelectric member 3 is a single plate. In place of the single piezoelectric-member 3, other preferred embodiments of the present invention may apply a diaphragm which is formed by adhering, to a metallic plate, a member excluding the resin layer 39 from the piezoelectric diaphragm 30.

According to the present preferred embodiment, the diaphragm is preferably approximately square, however the diaphragm may be substantially rectangular. In this case, preferably, the conductive adhesive may be applied to the positions near the corners on both ends of one short side.

With the diaphragm of the unimorph structure, as shown in FIG. 1, the piezoelectric member is adhered near one corner of the metallic plate. In addition, the diaphragm may be formed by adhering the piezoelectric member at the center of the metallic plate, or, may be formed by adhering the piezoelectric member at one side of the metallic plate.

As mentioned above, the piezoelectric diaphragm according to preferred embodiments of the present invention may have any shape and structure in so far as the piezoelectric diaphragm is quadrilateral.

While preferred embodiments of the present invention have been described above, it is to be understood that variations and modifications will be apparent to those skilled in the art without departing the scope and spirit of the invention. The scope of the present invention, therefore, is to be determined solely by the following claims.

1-6. (canceled)

7. A piezoelectric electroacoustic transducer comprising:
a quadrilateral piezoelectric diaphragm arranged to be vibrated in a thickness direction of the diaphragm by applying an alternating signal to lead electrodes thereof;
a casing including a supporting portion disposed on an inner circumference of the casing, the supporting portion supporting an outer circumference of said piezoelectric diaphragm;
first and second terminals that are fixed to said casing so that inner connecting portions are exposed on said inner circumference of the casing; and
conductive adhesives electrically connecting the lead electrodes of the piezoelectric diaphragm and the inner connecting portions of the first and second terminals; wherein
one of said conductive adhesives is arranged between the inner connecting portion of said first terminal and one of the lead electrodes near one corner of said piezoelectric diaphragm; and
the other conductive adhesive is arranged between the inner connecting portion of said second terminal and the other lead electrode near another corner of said piezoelectric diaphragm which is adjacent to the one corner of said piezoelectric diaphragm.

8. A piezoelectric electroacoustic transducer according to claim 7, wherein the location of one of said conductive adhesives faces the location of the other conductive adhesive across said piezoelectric diaphragm.

9. A piezoelectric electroacoustic transducer according to claim 7, wherein the location of one of said conductive adhesives and the location of the other conductive adhesive are on one side of said piezoelectric diaphragm and near the corners at both ends of the one side.

10. A piezoelectric electroacoustic transducer according to claim 7, wherein said piezoelectric diaphragm includes a quadrilateral piezoelectric member in contact with a quadrilateral metallic plate, wherein one of said lead electrodes is disposed on the surface of the piezoelectric member, and another of said lead electrodes is the metallic plate.

11. A piezoelectric electroacoustic transducer according to claim 7, wherein said piezoelectric diaphragm includes a plurality of piezoelectric ceramic layers sandwiching an inner electrode, said piezoelectric diaphragm including principle surface electrodes on principle surfaces of the front and back sides of said piezoelectric diaphragm, wherein one of said lead electrodes is connected to the inner electrode and the another of said lead electrodes is connected to the principle surface electrodes.

12. A piezoelectric electroacoustic transducer according to claim 7, wherein an elastic adhesive is applied directly between the piezoelectric diaphragm and an inner connecting portion of one of said first and second terminals, and the conductive adhesive is disposed over the elastic adhesive so as to indirectly connect said inner connecting portion and said piezoelectric diaphragm.

13. A piezoelectric electroacoustic transducer according to claim 7, wherein the casing includes a receiving step having a height lower than the supporting portion and a predetermined space between the receiving step and the bottom surface of the diaphragm.

14. A piezoelectric electroacoustic transducer according to claim 7, further comprising an elastic sealant in a space between an entire circumference of the diaphragm and an inner circumference of the casing.

15. A piezoelectric electroacoustic transducer according to claim 7, wherein the casing includes a groove and a wall arranged to prevent a flow of the elastic sealant to a bottom wall of the casing.
